(19) United States
(12) Patent Application Publication
(10) Pub. No.: US 2023/0207278 A1
(43) Pub. Date: Jun. 29, 2023

(54) ATOMIC LAYER DEPOSITION COATED POWDER COATING FOR PROCESSING CHAMBER COMPONENTS

(71) Applicant: Lam Research Corporation, Fremont, CA (US)

(72) Inventor: Eric A. PAPE, Santa Cruz, CA (US)

(21) Appl. No.: 17/927,297

(22) PCT Filed: May 11, 2021
(86) PCT No.: PCT/US2021/031861

§ 371 Date: Nov. 22, 2022

Related U.S. Application Data
(60) Provisional application No. 63/031,263, filed on May 28, 2020.

(51) Int. Cl. H01J 37/32

(52) U.S. Cl. CPC H01J 37/32495; H01J 37/32119; C23C 4/11; H01J 2237/334

(57) ABSTRACT

A component for use in a plasma processing chamber is provided. A component body has a plasma facing surface. A coating is over the plasma facing surface, wherein the coating is formed by a method comprising spraying a surface of the component body with a spray formed from atomic layer deposition (ALD) coated particles to form the coating.

### CROSS-REFERENCE TO RELATED APPLICATION

This application claims the benefit of priority of U.S. Application No. 63/031,263, filed May 28, 2020, which is incorporated herein by reference for all purposes.

### BACKGROUND

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

The present disclosure generally relates to the manufacturing of semiconductor devices. More specifically, the disclosure relates to plasma chamber components used in manufacturing semiconductor devices.

During semiconductor wafer processing, plasma processing chambers are used to process semiconductor devices. Plasma processing chambers are subjected to plasmas. The plasmas may degrade plasma facing surfaces of components of the plasma processing chamber. Coatings may be placed over plasma facing surfaces of components of plasma processing chambers to protect the surfaces.

Some of the coatings may be applied using a spraying process. Atmospheric plasma spraying generally utilizes a single chemistry powder material with as tightly controlled particle distribution as feasible for control of particle melt temperature. Using two different chemistries of powders, either with equivalent or different size distributions, is challenging since the heat capacities and latent heats of different materials are different, as are the melting points and optimal temperatures and velocities for particle impact on a substrate to control coating properties.

Some coatings may be applied using aerosol deposition. Some aerosol deposition also use a single chemistry powder precursor. For aerosol deposition, the mechanical properties of the powder are critical to have an appropriate shock-wave based deformation that adheres well to a substrate. Some slightly mixed powders to provide mixed stoichiometry or mixed chemistry are utilized in some aerosol deposition. Since the particles are not in a melt state, material diffusion between different types of particles is poor.

### SUMMARY

To achieve the foregoing and in accordance with the purpose of the present disclosure, a component for use in a plasma processing chamber is provided. A component body has a plasma facing surface. A coating is over the plasma facing surface, wherein the coating is formed by a method comprising spraying a surface of the component body with a spray formed from atomic layer deposition (ALD) coated particles to form the coating.

In another manifestation, a component for use in a plasma processing chamber system is provided. A component body has a plasma facing surface. A coating is on the plasma facing surface, wherein the coating comprises at least one of a metal oxide, a metal fluoride, and metal oxyfluoride, and wherein the coating comprises a matrix of a first material of a metal oxide or silicon oxide with particles of a second material of a metal oxide or silicon oxide, wherein either the first material is different than the second material or a phase of the first material is different than a phase of the second material.

In another manifestation, a method for coating a component body is provided. A surface of the component body is sprayed with a spray formed from atomic layer deposition (ALD) coated particles to form a coating.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-B are schematic cross-sectional views of a component processed according to an embodiment.

FIG. 3 is a schematic cross-sectional view of an atomic layer deposition coated particle.

FIG. 4 is a schematic view of a plasma processing chamber that may be used in an embodiment.

FIG. 5 is an enlarged schematic cross-sectional view of a coating used in an embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

For plasma processing chamber components, ceramic alumina (aluminum oxide (Al₂O₃)) is a common component material. Ceramic alumina may be used for items such as dielectric inductive power windows or gas injectors. Alumina has some plasma etch resistance. More etch-resistant coatings would provide additional protection to such plasma chamber components.

Coatings of mixed materials, such as a mixture of alumina and yttria (yttrium oxide (Y₂O₃)) may be deposited over an alumina component to provide a protective coating. The coating may be applied by aerosol deposition or thermal spraying. Mixed composition powders (some particles yttria, some particles alumina) have been used to create yttria/alumina/oxygen coatings with moderately controlled stoichiometry in both aerosol deposition and thermal spray coat. In general, this stoichiometry control is poor and often has microscale and macroscale spatial variation due to inadequate mixing during the ballistic trajectory, as well as poor mixing once adhering to the target substrate.

Atomic layer deposition (ALD) coated nanometer and micron sized powders of one material ALD coated over particles of another material have been developed to be sintered together to be used with fuel cells. ALD coating of particles provide particles with a well defined powder size morphology and distribution that are coated with an ALD coating to create an integral number of layers over these particles,

An embodiment applies ALD coated particles to a surface of a component through a spraying process to create extremely well defined particle stoichiometry. This process allows for a much more robust and uniform mixed-metal oxide type coating either through particle-based coating techniques such as aerosol deposition or APS (atmospheric plasma spraying) or SPS (suspension plasma spraying).

With an ALD coating of a different material than the bulk material of the particle core, one is able to carefully control the stoichiometry of different metal oxides. Additionally, there is intimate contact between the two materials, so that both in the liquid melt in an APS plume, as well as mechanical impact in aerosol deposition, there will be good mixing on a micro and nanoscale, creating very uniform materials. With aerosol deposition, there might not be perfect mixing, but instead, a well defined phase structure is provided. For example, one particle shell may create a skeleton of one phase structure and the core of another phase structure will fill the rest of the space. In some embodiments, after aerosol deposition, a post anneal may be used to create a better stoichiometry or to alter stresses in the coating.

In various embodiments, fluorinated aluminum (Al) or yttrium (Y) ALD coatings may be formed over alumina or yttria. In other embodiments, an yttria ALD coating may be formed over alumina, or an alumina ALD coating may be formed over yttria. In various embodiments, the ALD coatings may comprise, alumina, yttria, yttrium fluoride. Other embodiments may have ALD coatings of other rare earth oxides and fluorides including hafnium (Hf), erbium (Er), Y, etc. In various embodiments, the particles may be ALD coated with at least one of silicon oxide, metal oxides, metal fluorides, and metal oxyfluorides. The metals may be from the lanthanide series.

In various embodiments, the particles may be a silicon or metal oxide, fluoride, or oxyfluoride. Materials used for ALD coatings may instead be used as materials for the particles, as long as the material for the ALD coating is of a different material than the material of the particle. In some embodiments, the materials for the ALD coatings may be the same as the materials for the particle but may be different phases. For example, the material of the particles may have a cubic phase structure and the material of the ALD coatings may have a rhombic or gamma phase structure. As a result, the ALD coating and particles may have different Gibbs free energy and different thermodynamics. The phase structure may be determined using X-ray powder diffraction.

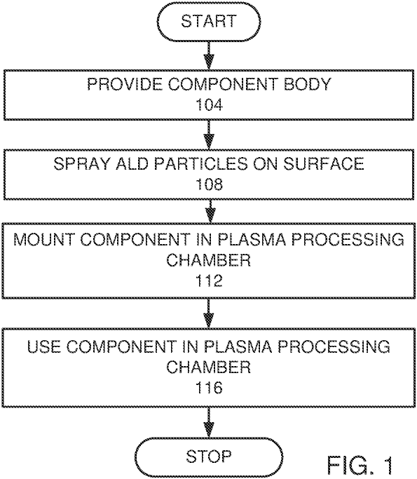

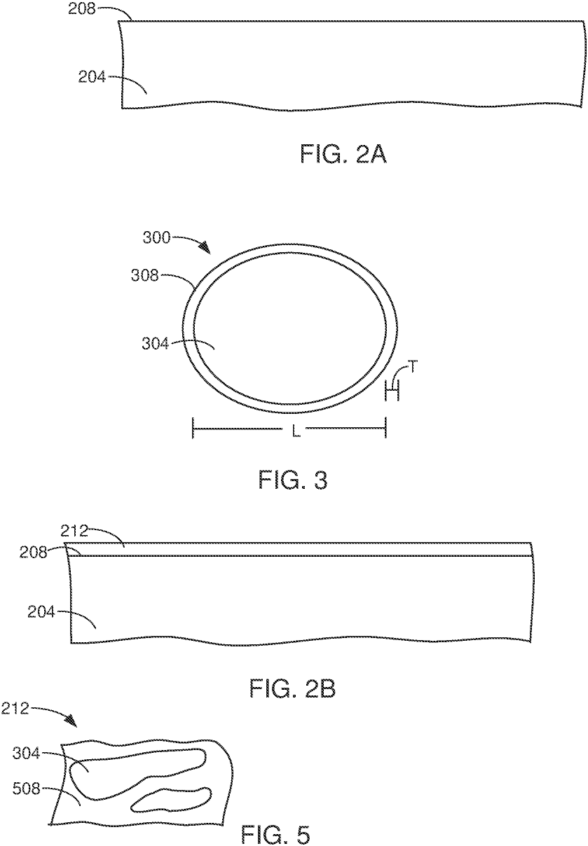

To facilitate understanding, FIG. 1 is a high level flow chart of a process used in an embodiment. A component body is provided (step 104). FIG. 2A is a schematic cross-sectional view of part of a component body 204 that is used in an embodiment. In this example, the component body 204 is a ceramic alumina dielectric inductive power window. The component body 204 has a surface 208. In this embodiment, the surface 208 is a plasma facing surface. A plasma facing surface is a surface 208 that will be exposed to plasma when the component body 204 is used in a plasma processing chamber.

Next, the surface 208 is coated by spraying the surface 208 of the component body 204 with spray formed from atomic layer deposition (ALD) coated particles. FIG. 3 is a schematic cross-sectional view of an ALD coated particle 300. The ALD coated particle 300 comprises a particle core 304 of a first material and an ALD coating 308 of a second material. In this embodiment, the first material is different than the second material. In this embodiment, the ALD coating 308 completely encapsulates the particle core 304. In this embodiment, the particle core 304 is yttria and the ALD coating 308 is alumina. The particle core 304 has a length L. If the particle core 304 was spherical, the length L would be the diameter of the particle core 304. In this embodiment, the length L of the particle is in the range of 10 nanometers (nm) to 100 microns. The ALD coating 308 has a thickness T. In this embodiment, the thickness T is in the range from 0.3 Å (one monolayer) to 2000 nm. In this embodiment, the ALD coating 308 may be 5 to 100 monolayers thick in order to provide an ALD coating 308 that survives aerosol deposition impact and to provide a desired matrix structure around the particle cores 304. The impact of the ALD coated particles 300 during aerosol deposition may melt or plastically deform the ALD coated particles 300. So the ALD coating 308 may need to be thick enough to recrystallize in a controlled manner. Generally, the ALD coating 308 has a uniform coating depth. However, some variation may be introduced by the ALD reaction process.

In this embodiment, the spraying the surface 208 is accomplished by providing an aerosol deposition of the ALD coated particles 300. Aerosol deposition is achieved by passing a carrier gas through a fluidized bed of solid powder mixture. Driven by a pressure difference, the powder mixture particles are accelerated through a nozzle, forming an aerosol jet at its outlet. The aerosol is then directed at the surface 208 of the component body 204, where the aerosol jet impacts the surface with high velocity. The ALD coated particles 300 break up into solid nanosized fragments, forming a coating. Optimization of carrier gas species, gas consumption, standoff distance, and scan speed provides a high-quality coating. FIG. 2B is a schematic cross-sectional view of the component body 204 after the surface 208 is coated by spraying the surface 208 of the component body 204 with spray formed from atomic layer deposition (ALD) coated particles 300 forming a coating 212.

The component body 204 is mounted in a plasma processing chamber (step 112). In this example, the component body 204 is mounted in the plasma processing chamber as a dielectric inductive power window. The plasma processing chamber is used to process a substrate (step 116), where a plasma is created within the chamber to process a substrate, such as etching the substrate, and the coating 212 is exposed to the plasma. The coating 212 provides increased etch resistance to protect the surface 208 of the component body 204.

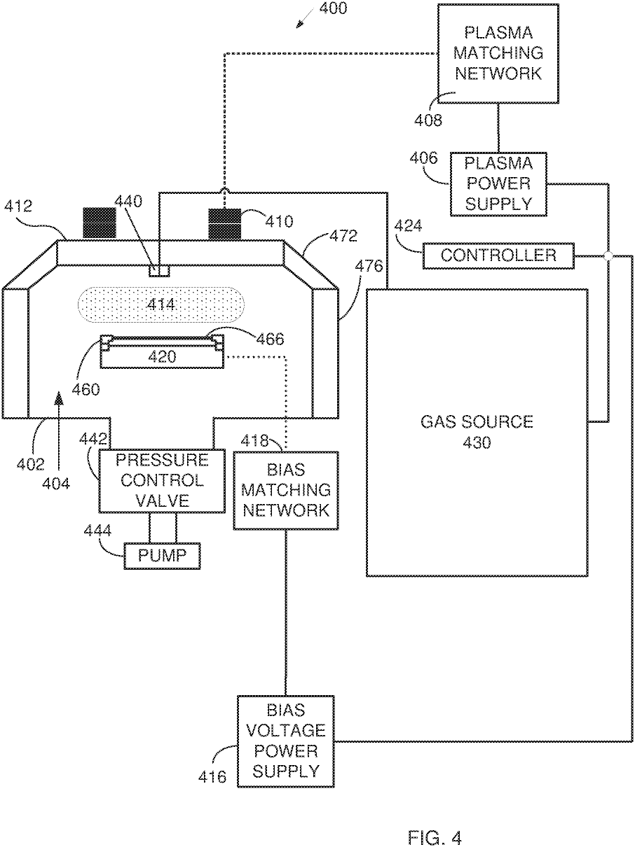

FIG. 4 schematically illustrates an example of a plasma processing chamber system 400 that may be used in an embodiment. The plasma processing chamber system 400 includes a plasma reactor 402 having a plasma processing confinement chamber 404 therein. A plasma power supply 406, tuned by a plasma matching network 408, supplies power to a transformer coupled plasma (TCP) coil 410 located near a dielectric inductive power window 412 to create a plasma 414 in the plasma processing confinement chamber 404 by providing an inductively coupled power. A pinnacle 472 extends from a chamber wall 476 of the plasma processing confinement chamber 404 to the dielectric inductive power window 412 forming a pinnacle ring. The pinnacle 472 is angled with respect to the chamber wall 476 and the dielectric inductive power window 412, such that the interior angle between the pinnacle 472 and the chamber wall 476 and the interior angle between the pinnacle 472 and the dielectric inductive power window 412 are each greater than 90° and less than 180°. The pinnacle 472 provides an angled ring near the top of the plasma processing confinement chamber 404, as shown. The TCP coil (upper power source) 410 may be configured to produce a uniform diffusion profile within the plasma processing confinement chamber 404. For example, the TCP coil 410 may be configured to generate a toroidal power distribution in the plasma 414. The dielectric inductive power window 412 is provided to separate the TCP coil 410 from the plasma processing confinement chamber 404 while allowing energy to pass from the TCP coil 410 to the plasma processing confinement chamber 404. A wafer bias voltage power supply 416 tuned by a bias matching network 418 provides power to an electrode 420 to set the bias voltage on the substrate 466. The substrate 466 is supported by the electrode 420. A controller 424 controls the plasma power supply 406 and the wafer bias voltage power supply 416.

The plasma power supply 406 and the wafer bias voltage power supply 416 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 406 and wafer bias voltage power supply 416 may be appropriately sized to supply a range of powers in order to achieve desired process performance. For example, in one embodiment, the plasma power supply 406 may supply the power in a range of 50 to 5000 Watts, and the wafer bias voltage power supply 416 may supply a bias voltage of in a range of 20 to 2000 volts (V). In addition, the TCP coil 410 and/or the electrode 420 may be comprised of two or more sub-coils or sub-electrodes. The sub-coils or sub-electrodes may be powered by a single power supply or powered by multiple power supplies.

As shown in FIG. 4, the plasma processing chamber system 400 further includes a gas source/gas supply mechanism 430. The gas source 430 is in fluid connection with plasma processing confinement chamber 404 through a gas inlet, such as a gas injector 440. The gas injector 440 may be located in any advantageous location in the plasma processing confinement chamber 404 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 404. More preferably, the gas injector is mounted to the dielectric inductive power window 412. The gas injector may be mounted on, mounted in, or form part of the power window. The process gases and by-products are removed from the plasma process confinement chamber 404 via a pressure control valve 442 and a pump 444. The pressure control valve 442 and pump 444 also serve to maintain a particular pressure within the plasma processing confinement chamber 404. The pressure control valve 442 can maintain a pressure of less than 1 torr during processing. An edge ring 460 is placed around the substrate 466. The gas source/gas supply mechanism 430 is controlled by the controller 424. A Kiyo by Lam Research Corp. of Fremont, CA, may be used to practice an embodiment.

In various embodiments, the component may be other parts of a plasma processing chamber, such as confinement rings, edge rings, the electrostatic chuck, ground rings, chamber liners, door liners, the pinnacle, or other components. Other components of other types of plasma processing chambers may be used. For example, plasma exclusion rings on a bevel etch chamber may be coated in an embodiment. In another example, the plasma processing chamber may be a dielectric processing chamber or conductor processing chamber. In some embodiments one or more, but not all surfaces are coated. The component may be made of a ceramic material, metal, or dielectric material. For example, a pinnacle may be aluminum. In other embodiments, the component may be part of other substrate processing chambers may be used. Such substrate processing chambers may not use plasma processes.

Aerosol deposition provides a high-density coating of solid unmelted material with nanograins. The resulting coating created by aerosol deposition of ALD coated particles 300 of an yttria particle core 304 with an alumina ALD coating 308 results in an alumina skeleton of a thin alumina layer matrix incorporated between spheres of yttria particle cores 304. The stoichiometry of the coating 212 and the structure of the coating 212 may be finely tuned by controlling the thickness T of the ALD coating 308 and the length of the particle core 304. Due to the high pressures, high inertias, and high velocities, the resulting structure may be complex with some material intermixing and some phase recrystallization due to the high pressure impact.

FIG. 5 is an enlarged schematic cross-sectional view of the coating 212 formed using aerosol deposition. The coating 212 comprises particle cores 304 and a skeleton 508 formed from material from the ALD coating 308, shown in FIG. 3. The skeleton 508 is a thin alumina layer between the yttria particle cores 304. In this embodiment, the aerosol deposition causes the particle cores 304 to flatten, so that the coating is formed by flattened particle cores 304 surrounded by a skeleton 508.

This embodiment provides a coating 212 of different materials at very controlled and consistent ratios, to be able to fine tune properties of the coating 212. The resulting coating 212 may have a low porosity and high mechanical strength. This embodiment provides the ability to coat at low temperatures for controlled intrinsic stresses. Some of the resulting properties that may be controlled are plasma etch resistance, coefficient of thermal expansion, resistance against electrostatic erosion, the percentages of each chemical phase, size of each phase, intrinsic stresses (i.e. stresses at various temperatures due to coating impact and coefficient of thermal expansion mismatches), level of fluorination versus oxidation, density, and porosity of the coating 212. In addition, since alumina is less brittle than yttria, the deposition efficiency and the retention of the overall aerosol deposition coating are increased and the matrix is more uniform at a microscale. In some embodiments, a post anneal process may be provided to provide a truly mixed phase and/or reduce stress.

In another embodiment, ALD coated particles 300 comprise a particle core 304 of yttria and an ALD coating 308 of yttrium fluoride (YF₃). In this embodiment, the ALD coated particles 300 are sprayed using a thermal spray. In this embodiment, the thermal spray is an atmospheric plasma spray. For atmospheric plasma spraying in this embodiment, the particles may be about 10 microns in diameter (at least 90 mass-% of the particles are in the range of 5 µm - 20 µm diameter, or better (D₅₀ is in the range of 5 µm to 20 µm). The resulting ALD coating 308 may comprise yttrium oxyfluoride (YOF). Coatings 212 formed using thermal spray may have more intermixing due to melting than coatings 212 formed by aerosol deposition.

Atmospheric plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquefying high melting point materials such as ceramics. ALD coated particles 300 of the desired materials are injected into the jet, melted, and then accelerated towards the substrate so that the molten or plasticized material coats the surface of the component and cools, forming a solid, conformal coating. These processes are distinct from vapor deposition processes that use vaporized material instead of molten material.

An example of a recipe for plasma spraying the coating 212 is as follows. A carrier gas is pushed through an arc cavity and out through a nozzle. In the cavity, a cathode and anode comprise parts of the arc cavity. The cathode and anode are maintained at a large DC bias voltage, until the carrier gas begins to ionize, forming the plasma. The hot, ionized gas is then pushed out through the nozzle forming the torch. Into the chamber near the nozzle is injected fluidized ALD coated particles 300, tens of micrometers in size. These ALD coated particles 300 are heated by the hot, ionized gas in the plasma torch such that they exceed the melting temperature of the ALD coated particles 300. The jet of plasma and melted ALD coated particles 300 are then aimed at a surface 208 of the component body 204. The ALD coated particles 300 impact the substrate, and are flatten and cooled to form the coating 212.

The ALD coated particles 300 when melted during an atmospheric spray process creates a stoichiometric melt, where the ratio of the different materials is precisely controlled and uniform. In some embodiments, the ratio of the materials in the stoichiometric melt may be controlled to provide a coating 212 of one or more of yttrium aluminum garnet (Y₃Al₅O₁₂ (YAG)), yttrium aluminum monoclinic (Y₄Al₂O₉ (YAM)), or yttrium aluminum perovskite (YAlO₃ (YAP)). In various embodiments, the melt has an yttrium to aluminum ratio in the range of 4:1 to 1:4 by molar number. Since this process completely melts the alumina and yttria at precise stoichiometric controls, a single phase coating 212 is provided.

Various embodiments may use various spraying processes, such as at least one of thermal spray processes such as wire arc spraying, air plasma spraying, atmospheric plasma spraying, suspension plasma spraying, low-pressure plasma spraying, very low-pressure plasma spraying, cold spraying, kinetic energy spraying, and aerosol deposition. Suspension plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquifying high melting point materials such as ceramics. A liquid suspension of solid particles, of about 1 micron in size, to be deposited in a liquid medium is fed to the torch. The torch melts the solid particles of the desired material. The melted material is injected into the jet and then accelerated towards the component so that the molten or plasticized material coats the surface 208 of the component and then is cooled, forming a solid, conformal coating. The suspension plasma spraying may be used to provide a higher density coating 212.

In other embodiments, different ALD layers may be of different materials, so that the ALD particles may provide three or more different materials. For example, ALD particles with an alumina particle may have a first ALD coating of yttria surrounding the alumina particle and a second ALD coating of magnesium fluoride (MgF₂) surrounding the first ALD coating.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

1. A component for use in a plasma processing chamber, comprising:
a component body with a plasma facing surface; and
a coating over the plasma facing surface, wherein the coating is formed by a method comprising aerosol deposition spraying a surface of the component body with a spray formed from atomic layer deposition (ALD) coated particles to form the coating.

2. The component, as recited in claim 1, wherein the ALD coated particles have ALD coatings of at least one of a metal oxide, a metal fluoride, and metal oxyfluoride.

3. The component, as recited in claim 1, wherein the ALD coated particles have particle cores of at least one of silicon oxide or alumina.

4. The component, as recited in claim 1, wherein the ALD coated particles have ALD coatings of at least one of silicon oxide, alumina, or fluorinated aluminum.

5. (canceled)

6. The component, as recited in claim 1, wherein particles of the ALD coated particles comprise particle cores that are of a different material than a material forming the ALD coating.

7. The component, as recited in claim 1, wherein the ALD coated particles comprise particle cores that are of a same material as a material forming the ALD coating and wherein the particle cores have a different phase structure than the ALD coating.

8. A component for use in a plasma processing chamber system, comprising:
a component body with a plasma facing surface; and
a coating on the plasma facing surface, wherein the coating comprises at least one of a metal oxide, a metal fluoride, and metal oxyfluoride, and wherein the coating comprises a matrix of a first material of a metal oxide or silicon oxide with particles of a second material of a metal oxide or silicon oxide, wherein either the first material is different than the second material or a phase of the first material is different than a phase of the second material.

9. A method for coating a component body, wherein the method comprises aerosol deposition spraying a surface of the component body with spray formed from atomic layer deposition (ALD) coated particles to form a coating.

10. The method, as recited in claim 9, wherein the ALD coated particles have ALD coatings of at least one of a metal oxide, a metal fluoride, and metal oxyfluoride.

11. The method, as recited in claim 9, wherein the ALD coated particles comprise particle cores of at least one of silicon or alumina.

12. The method, as recited in claim 9, wherein the ALD coated particles have ALD coatings of at least one of silicon oxide, alumina or fluorinated aluminum.

13. (canceled)

14. (canceled)

15. (canceled)

16. The method, as recited in claim 9, wherein particle cores of the ALD coated particles are of a different material than a material forming the ALD coating.

17. The method, as recited in claim 9, wherein particle cores of the ALD coated particles are of a same material as a material forming the ALD coating and wherein the particle cores have a different phase structure than the ALD coating.

18. The method, as recited in claim 9, wherein the component body is adapted for use in a plasma processing chamber and wherein the component body has a plasma facing surface, wherein the coating is formed over the plasma facing surface.

19. The coating as recited in claim 1, wherein the coating is formed by solid unmelted material with nanograins.

20. The coating as recited in claim 1, wherein the coating is formed by a skeleton surrounding particle cores.

21. The coating as recited in claim 20, wherein the skeleton comprises alumina.

22. The component, as recited in claim 8, wherein the matrix comprises at least one of a metal oxide, a metal fluoride, and metal oxyfluoride.

23. The component, as recited in claim 8, wherein the matrix comprises at least one of silicon and aluminum.
